(19) United States
(12) Patent Application Publication
(10) Pub. No.: US 2025/0192083 A1
(43) Pub. Date: Jun. 12, 2025

(54) SEMICONDUCTOR PACKAGE

(71) Applicant: Samsung Electronics Co., Ltd., Suwon-si (KR)

(72) Inventors: Jongpa HONG, Suwon-si (KR); Dugjoong KIM, Suwon-si (KR); Keumhee MA, Suwon-si (KR); Jongbeom PARK, Suwon-si (KR)

(73) Assignee: Samsung Electronics Co., Ltd., Suwon-si (KR)

(21) Appl. No.: 18/923,974

(22) Filed: Oct. 23, 2024

(30) Foreign Application Priority Data
Dec. 6, 2023 (KR) 10-2023-0175443

(51) Int. Cl. H01L 23/00; H01L 25/065

(52) U.S. Cl. CPC H01L 24/05; H01L 24/13; H01L 24/16; H01L 25/0657; H01L 2224/0401; H01L 2224/05557; H01L 2224/05571; H01L 2224/05611; H01L 2224/13082; H01L 2224/13582; H01L 2224/13687; H01L 2224/16147; H01L 2225/06513; H01L 2225/06544; H01L 2225/06565

(57) ABSTRACT

A semiconductor package may include a semiconductor substrate defining a trench extending in a vertical direction from an upper surface of the semiconductor substrate, an insulating layer on the semiconductor substrate, a first through electrode penetrating the semiconductor substrate, a bonding pad in the trench, and a second through electrode. A first surface of the bonding pad may be in contact with the first through electrode and a second surface of the bonding pad, may be in contact with the second through electrode in contact. The second through electrode may be apart from the insulating layer in a horizontal direction. The vertical direction may be perpendicular to the upper surface of the semiconductor substrate. The first surface and second surface of the bonding pad may be opposite each other.

### CROSS-REFERENCE TO RELATED APPLICATION

This application is based on and claims ranking under 35 U.S.C. § 119 to Korean Patent Application No. 10-2023-0175443, filed on Dec. 6, 2023 in the Korean Intellectual Property office, the disclosure of which is incorporated by reference herein in its entirety.

### BACKGROUND

Inventive concepts relate to a semiconductor package including stacked semiconductor chips.

Electronic devices have become more compact and lighter due to rapid developments in the electronics industry and demands of users. As electronic devices become smaller and lighter, semiconductor packages used in the electronic devices also become smaller and lighter, and in addition, the semiconductor packages may require high reliability together with high performance and large capacity. As the semiconductor packages have high performance and high capacity, power consumption of the semiconductor packages may increase. Accordingly, the importance of the structure of a semiconductor package for responding to the size/performance of the semiconductor packages and supplying stable power to the semiconductor package may be increasing.

### SUMMARY

Inventive concepts provide a semiconductor package including stacked semiconductor chips.

According to according to an embodiment of inventive concepts, a semiconductor package may include a semiconductor substrate defining a trench extending in a vertical direction from an upper surface of the semiconductor substrate, the vertical direction being perpendicular to the upper surface of the semiconductor substrate; an insulating layer on the semiconductor substrate; a first through electrode penetrating the semiconductor substrate; a bonding pad in the trench, a first surface of the bonding pad being in contact with the first through electrode and a second surface of the bonding pad being opposite the first surface of the bonding pad; and a second through electrode in contact with the second surface of the bonding pad. The second through electrode may be apart from the insulating layer in a horizontal direction.

According to an embodiment of inventive concepts, a semiconductor package may include
a first semiconductor substrate defining a trench extending in a vertical direction from an upper surface of the first semiconductor substrate, the vertical direction being perpendicular to the upper surface of the first semiconductor substrate; a first insulating layer on the first semiconductor substrate, the first insulating layer including a hole corresponding to the trench; a first through electrode penetrating the first semiconductor substrate; a first bonding pad in the trench, a first surface of the first bonding pad facing the first through electrode, and a second surface of the first bonding pad being opposite the first surface of the first bonding pad and having a step; a second semiconductor substrate on the first insulating layer; a second insulating layer between the second semiconductor substrate and the first insulating layer, the second insulating layer being bonded to the first insulating layer; and a second through electrode penetrating the second semiconductor substrate and the second insulating layer, the second through electrode being bonded to the second surface of the first bonding pad. The second through electrode may be apart from the first insulating layer in a horizontal direction.

According to according to an embodiment of inventive concepts, a semiconductor package may include a first semiconductor chip and a second semiconductor chip bonded to each other. The first semiconductor chip may include a first semiconductor substrate defining a trench extending in a vertical direction from an upper surface of the first semiconductor substrate, a first insulating layer on the first semiconductor substrate, a first through electrode penetrating the first semiconductor substrate, and a bonding pad in the trench. The vertical direction may be perpendicular to the upper surface of the first semiconductor substrate. A first surface of the bonding pad may be in contact with the first through electrode. A second surface of the bonding pad may be opposite the first surface of the bonding pad. The second semiconductor chip may include a second semiconductor substrate, a second insulating layer between the second semiconductor substrate and the first insulating layer, and a second through electrode penetrating the second semiconductor substrate and the second insulating layer. The second through electrode may be in contact with the second surface of the bonding pad. The second through electrode may be apart from the first insulating layer in a horizontal direction.

### BRIEF DESCRIPTION OF THE DRAWINGS

Embodiments will be more clearly understood from the following detailed description taken in conjunction with the accompanying drawings in which:

FIG. 1 is a schematic cross-sectional view of a semiconductor package according to an embodiment;

FIG. 2 is an enlarged view of region “CX1” in FIG. 1;

FIG. 3 is a plan view of a through electrode attached to a bonding pad, according to an embodiment;

FIGS. 4 through 9 are cross-sectional views illustrating a manufacturing method of a semiconductor chip, according to embodiments;

FIG. 10 is a cross-sectional view of a semiconductor package according to an embodiment;

FIG. 11 is an enlarged view of region “CX2” in FIG. 10;

FIG. 12 is a cross-sectional view of a semiconductor package according to another embodiment;

FIG. 13 is a cross-sectional view of a semiconductor package according to another embodiment;

FIG. 14 is a cross-sectional view of a semiconductor package according to another embodiment;

FIG. 15 is a cross-sectional view of a semiconductor package according to another embodiment;

FIG. 16 is a cross-sectional view of a semiconductor package according to another embodiment;

FIG. 17 is a cross-sectional view of a semiconductor package according to another embodiment; and

FIG. 18 is a cross-sectional view of a semiconductor package according to another embodiment.

### DETAILED DESCRIPTION

Hereinafter, embodiments of inventive concepts are described in detail with reference to accompanying diagrams. However, inventive concepts are not limited to the embodiments described below, and may be embodied in various other forms. The embodiments below are provided not to allow inventive concepts to be thoroughly completed, but to sufficiently convey the scope of inventive concepts to those of skill in the art.

Expressions such as “at least one of,” if preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

The notion that elements are “substantially the same” may indicate that the element may be completely the same and may also indicate that the elements may be determined to be the same in consideration of errors or deviations occurring during a process.

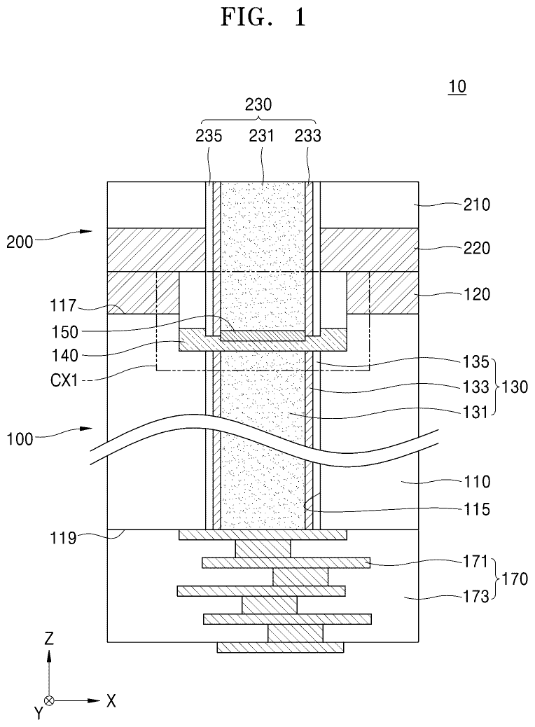

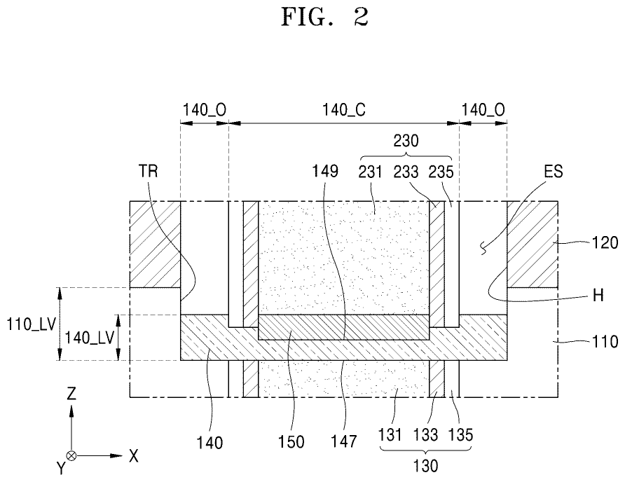

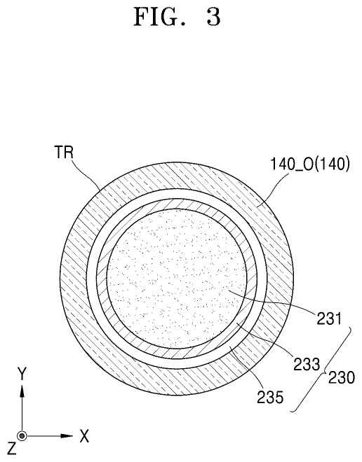

FIG. 1 is a schematic cross-sectional view of a semiconductor package 10 according to an embodiment. FIG. 2 is an enlarged view of region “CX1” in FIG. 1. FIG. 3 is a plan view of a second through electrode 230 attached to a bonding pad 140, according to an embodiment.

Referring to FIGS. 1 through 3, the semiconductor package 10 may include a first semiconductor chip 100 and a second semiconductor chip 200. The first semiconductor chip 100 may include a first semiconductor substrate 110, a first insulating layer 120, a first through electrode 130, the bonding pad 140, an alloy pad 150, and an interconnect structure 170.

The first semiconductor substrate 110 may include an upper surface 117 and a lower surface 119, which are opposite to each other. The upper surface 117 of the first semiconductor substrate 110 may be a backside surface of the first semiconductor substrate 110, and the lower surface 119 of the first semiconductor substrate 110 may be a frontside surface of the first semiconductor substrate 110. The upper surface 117 of the first semiconductor substrate 110 may be an inactive surface of the first semiconductor substrate 110, and the lower surface 119 of the first semiconductor substrate 110 may be an active surface of the first semiconductor substrate 110.

Hereinafter, a direction in parallel with the upper surface 117 of the first semiconductor substrate 110 may be defined as a horizontal direction (for example, X direction and/or Y direction), and a direction perpendicular to the upper surface 117 of the first semiconductor substrate 110 may be defined as a vertical direction (for example, Z direction). In addition, a horizontal width may be referred to as a length in the horizontal direction (for example, X direction and/or Y direction), and a vertical height may be referred to as a length in the vertical direction (for example, Z direction).

The first semiconductor substrate 110 may be formed from a semiconductor wafer. The first semiconductor substrate 110 may include, for example, silicon (Si). Alternatively, the first semiconductor substrate 110 may include a semiconductor element such as germanium (Ge), or a compound semiconductor, such as silicon carbide (SiC), gallium arsenide (GaAs), and indium arsenide (InAs). The first semiconductor substrate 110 may include a conductive region, for example, a well doped with impurities or a structure doped with impurities. In addition, the first semiconductor substrate 110 may have various device isolation structures such as a shallow trench isolation (STI) structure.

The first insulating layer 120 may be arranged on the upper surface 117 of the first semiconductor substrate 110. The first insulating layer 120 may include an oxide and/or a nitride. For example, the first insulating layer 120 may include at least one material of SiO, SiN, SiCN, SiCO, and a polymer material. For example, the polymer material may include benzocyclobutene (BCB), polyimide (PI), polybenzoxazole (PBO), Si, or epoxy. In some embodiments, the first insulating layer 120 may have a multi-layer structure including a plurality of insulating material layers stacked in the vertical direction (for example, Z direction).

According to an embodiment, a trench TR formed through a portion of the first semiconductor substrate 110 may be provided. The trench TR may be formed to extend in the vertical direction (Z direction) perpendicular to the upper surface 117 of the first semiconductor substrate 110. In addition, a hole H formed by penetrating the first insulating layer 120 in the vertical direction (Z direction) may be provided. Because the trench TR and the hole H are formed by being recessed in the vertical direction (Z direction) while the first insulating layer 120 is stacked on the first semiconductor substrate 110, a side surface of the first semiconductor substrate 110 in the trench TR and a side surface of the first insulating layer 120 in the hole H may be arranged on the same plane. In a plan view, the trench TR and the hole H may have circular cross-sections. In FIGS. 1 and 2, the trench TR and the hole H are illustrated having a constant width in the vertical direction (Z direction), but according to an embodiment, the width thereof may have a tapered shape in which the width thereof decreases toward the lower surface 119 of the first semiconductor substrate 110. According to another embodiment, the trench TR and the hole H may have a tapered shape in which the width thereof increases toward the lower surface 119 of the first semiconductor substrate 110 in the vertical direction (Z direction).

The first through electrode 130 may penetrate the first semiconductor substrate 110. The first through electrode 130 may be provided in a through hole 115 of the first semiconductor substrate 110 extending from the lower surface 119 to the upper surface 117 of the first semiconductor substrate 110. In addition, the first through electrode 130 may be exposed at the lower surface of the trench TR formed in the first semiconductor substrate 110. Accordingly, the upper surface 117 of the first through electrode 130 may be on the same plane as the bottom surface of the trench TR. In some embodiments, the horizontal width (or diameter) of the upper surface of the first through electrode 130 may be about 5 micrometers (μm) to about 30 μm, about 5 μm to about 20 μm, or about 5 μm to about 10 μm.

The first through electrode 130 may include a first conductive plug 131, a first conductive barrier layer 133, and a first via insulating layer 135. The first conductive plug 131 may extend lengthwise in the first semiconductor substrate 110 in the vertical direction (Z direction). The first conductive barrier layer 133 may be arranged on the side surface of the first conductive plug 131, and the first via insulating layer 135 may be arranged on the side surface of the first conductive barrier layer 133.

The first conductive plug 131 may have a column shape, and the first conductive barrier layer 133 may have a cylindrical shape surrounding a sidewall of the first conductive plug 131. In addition, the first via insulating layer 135 may have a cylindrical shape surrounding a sidewall of the first conductive barrier layer 133. The first conductive barrier layer 133 extends from a lower end to an upper end of the sidewall of the first conductive plug 131 and may cover the entire sidewall of the first conductive plug 131. For example, the first conductive plug 131 may include copper (Cu), nickel (Ni), aluminum (Al), gold (Au), silver (Ag), tungsten (W), titanium (Ti), tantalum (Ta), indium (In), molybdenum (Mo), manganese (Mn), cobalt (Co), tin (Sn), magnesium (Mg), rhenium (Re), beryllium (Be), gallium (Ga), ruthenium (Ru), or a combination thereof. The first conductive barrier layer 133 may include titanium (Ti), titanium nitride (TiN), tantalum (Ta), tantalum nitride (TaN), tungsten (W), tungsten nitride (WN), ruthenium (Ru), cobalt (Co), or a combination thereof. The first conductive plug 131 and the first conductive barrier layer 133 may be formed by using, for example, a physical vapor deposition (PVD) process, a chemical vapor deposition (CVD) process, and/or a plating process.

The first via insulating layer 135 may extend from the lower surface 119 to the upper surface 117 of the first semiconductor substrate 110 and may surround the sidewall of the first conductive barrier layer 133 arranged in the through hole 115 of the first semiconductor substrate 110. In addition, the first via insulating layer 135 may be arranged between the first conductive barrier layer 133 and the first semiconductor substrate 110. The first via insulating layer 135 may include an oxide. For example, the first via insulating layer 135 may include an ozone/tetra-ethyl ortho-silicate (O₃/TEOS)-based high aspect ratio process (HARP) oxide formed by using a sub-atmospheric CVD process.

According to the embodiment, the bonding pad 140 may be arranged on the upper surface 117 of the first semiconductor substrate 110 in the trench TR. The bonding pad 140 may be arranged between the first through electrode 130 and the second through electrode 230 and may be physically and electrically connected to the upper surface of the first through electrode 130. In addition, the bonding pad 140 may be physically and electrically connected to the lower surface of the second through electrode 230. The bonding pad 140 may have a first surface 147 in contact with the first through electrode 130 and a second surface 149 opposite the first surface 147 and in contact with the second through electrode 230.

The bonding pad 140 may have a width greater than that of the first through electrode 130 in the horizontal direction (X direction and/or Y direction). The bonding pad 140 may completely cover the bottom surface of the trench TR in the trench TR, that is, the upper surface portion of the first semiconductor substrate 110 in the trench TR. In a plan view, the bonding pad 140 may have a circular shape. In this case, the diameter of the bonding pad 140 may be greater than the diameter of the first through electrode 130 and the diameter of the second through electrode 230.

According to an embodiment, the bonding pad 140 may be formed in the trench TR, but may be formed to fill only a portion of the area in the trench TR without entirely filling the area of the trench TR. In other words, a vertical level 140_LV of the uppermost end of the second surface 149 with respect to the first surface 147 of the bonding pad 140 may be lower than a vertical level 110_LV of the uppermost end of the first semiconductor substrate 110 with respect to the first surface 147. When the vertical level 140_LV of the uppermost end of the second surface 149 of the bonding pad 140 is higher than the vertical level 110_LV of the uppermost end of the first semiconductor substrate 110, the bonding pad 140 may be in contact with a portion of the first insulating layer 120, and in this case, a metal material constituting the bonding pad 140 may penetrate the first insulating layer 120. Accordingly, the vertical level 140_LV of the uppermost end of the second surface 149 of the bonding pad 140 may be formed to be lower than the vertical level 110_LV of the uppermost end of the first semiconductor substrate 110.

According to an embodiment, the second surface 149 of the bonding pad 140 may have a stepped profile. In a cross-section view, the thickness of the bonding pad 140 may decrease toward the center thereof. A center portion of the first surface 147 of the bonding pad 140 may be in contact with the alloy pad 150, and an outer portion of the center portion of the first surface 147 may be in contact with a second conductive barrier layer 233 and the second via insulating layer 235 of the second through electrode 230.

An opening portion ES may be provided between the side surface of the second through electrode 230 and the side surface of the first insulating layer 120 and between the side surface of the second through electrode 230 and the side surface of the first semiconductor substrate 110. In this case, the outermost portion of the first surface 147 of the bonding pad 140 may be exposed at the opening portion ES in the trench TR. A space surrounded by the first insulating layer 120, the first semiconductor substrate 110, and the bonding pad 140 on the outer wall of the second via insulating layer 235 may be defined as the opening portion ES.

A center portion 140_C of the bonding pad 140 may be in contact with the alloy pad 150, the second conductive barrier layer 233, and the second via insulating layer 235, and the outer portion 140_O of the bonding pad 140 may be exposed in the opening portion ES. In a plan view, the outer portion 140_O of the bonding pad 140 may have a ring shape continuously extending along the sidewall of the second through electrode 230. The bonding pad 140 may include, for example, at least one of Sn or Ge.

According to the embodiment, the alloy pad 150 may be arranged between a second conductive plug 231 and the bonding pad 140. In this case, the lower surface of the alloy pad 150 may be in contact with the bonding pad 140, and the upper surface opposite to the lower surface of the alloy pad 150 may be in contact with the second conductive plug 231. In this case, the lower surface of the alloy pad 150 may be offset with respect to the lower surface of the second conductive barrier layer 233 and the lower surface of the second via insulating layer 235 in the vertical direction (Z direction).

The alloy pad 150 may include an alloy material formed by reacting a metal material of the second conductive plug 231 with a metal material of the bonding pad 140. For example, the second conductive plug 231 may include Cu, the bonding pad 140 may include Sn, and the alloy pad 150 may include a copper-tin (Cu—Sn) alloy. For example, the alloy pad 150 may include an intermetallic compound. When the bonding force between the metals constituting the second conductive plug 231 or the bonding force between the metals constituting the bonding pad 140 is strong, the bonding pad 140 may not be formed. In other words, when the bonding force between the metals constituting the second conductive plug 231 or the bonding force between the metals constituting the bonding pad 140 is weaker than the bonding force between two or more metals constituting the bonding pad 140, the bonding pad 140 may be stably formed.

The second semiconductor chip 200 may be arranged on the first semiconductor chip 100. The lower surface of the second semiconductor chip 200 may be attached to the upper surface of the first semiconductor chip 100. The first semiconductor chip 100 and the second semiconductor chip 200 may be bonded to each other by using a direct bonding method, for example, a hybrid direct bonding method. The first through electrode 130 of the first semiconductor chip 100 and the second through electrode 230 of the second semiconductor chip 200 may be aligned and bonded to each other in the vertical direction (Z direction). In addition, the upper surface of the first insulating layer 120 of the first semiconductor chip 100 may be bonded to the lower surface of a second insulating layer 220 of the second semiconductor chip 200. Each of the upper surface of the first insulating layer 120 of the first semiconductor chip 100 and the lower surface of the second insulating layer 220 of the second semiconductor chip 200 may have bonding forces suitable for bonding by using a plasma treatment process and/or a wet treatment process. For example, bonding between the first semiconductor chip 100 and the second semiconductor chip 200 may be achieved by contacting a bonding surface of the first semiconductor chip 100 and a bonding surface of the second semiconductor chip 200 and then respectively applying heat to the bonding pad 140 and the first insulating layer 120 of the first semiconductor chip 100 to the second through electrode 230 and the second insulating layer 220 of the second semiconductor chip 200.

In some embodiments, a material of the first insulating layer 120 may be the same as a material of the second insulating layer 220. For example, the first insulating layer 120 and the second insulating layer 220 may include silicon oxide.

In some embodiments, the material of the first insulating layer 120 may be different from the material of the second insulating layer 220. For example, the first insulating layer 120 may include silicon nitride, and the second insulating layer 220 may include silicon oxide.

The second through electrode 230 may be bonded to the second surface 149 of the bonding pad 140. The second through electrode 230 may include a second conductive plug 231, a second conductive barrier layer 233, and a second via insulating layer 235. The second conductive plug 231 may extend lengthwise in a second semiconductor substrate 210 in the vertical direction (Z direction). The second conductive barrier layer 233 may be arranged on the side surface of the second conductive plug 231, and the second via insulating layer 235 may be arranged on the side surface of the second conductive barrier layer 233. The second conductive plug 231 may be substantially the same as the first conductive plug 131, and the second conductive barrier layer 233 may be substantially the same as the first conductive barrier layer 133. In addition, the second via insulating layer 235 may be substantially the same as the first via insulating layer 135. Accordingly, detailed descriptions of the second conductive plug 231, the second conductive barrier layer 233, and the second via insulating layer 235 are omitted below.

In some embodiments, in a plan view, the bonding pad 140, and the first and second conductive plugs 131 and 231 may each be circular. In some embodiments, in a plan view, the bonding pad 140, and the first and second conductive plugs 131 and 231 may each have a polygonal shape such as a square.

In some embodiments, the first semiconductor chip 100 may include a plurality of bonding pads 140 apart from each other in the horizontal direction (for example, X direction and/or Y direction). In this case, a distance between centers (that is, a pitch interval) of two neighboring bonding pads 140 may be between about 10 μm and about 50 μm or between about 10 μm and about 30 μm.

In some embodiments, the horizontal width of the bonding pad 140 may be between about 10 μm and about 50 μm, between about 10 μm and about 30 μm, and between about 10 μm and about 20 μm. In some embodiments, the vertical height of the bonding pad 140 may be between about 1 μm and about 10 μm.

The interconnect structure 170 may be arranged on the lower surface 119 of the first semiconductor substrate 110. The interconnect structure 170 may include a back-end-of-line (BEOL) structure provided on the lower surface 119 of the first semiconductor substrate 110. The interconnect structure 170 may include an interconnect insulating layer 173 provided on the lower surface 119 of the first semiconductor substrate 110 and a conductive interconnect pattern 171 provided in the interconnect insulating layer 173. The conductive interconnect pattern 171 of the interconnect structure 170 may be electrically connected to the through electrode 130. In addition, the interconnect structure 170 may be electrically connected to the integrated circuit of the first semiconductor chip 100.

The conductive interconnect pattern 171 of the interconnect structure 170 may include a plurality of interconnect lines and a plurality of interconnect vias. The plurality of interconnect lines and the plurality of interconnect vias may be coated by the interconnect insulating layer 173. Each of the plurality of interconnect lines may extend in the horizontal direction (for example, X direction and/or Y direction) in the interconnect insulating layer 173. The plurality of interconnect lines may be at different levels in the interconnect insulating layer 173 in the vertical direction (for example, Z direction) to form a multi-layer interconnect structure. The plurality of interconnect vias may extend between the plurality of interconnect lines at different vertical levels from each other, and may electrically connect between the plurality of interconnect lines at different vertical levels.

For example, the plurality of interconnect lines and the plurality of interconnect vias may include a metal such as Cu, Al, W, Ti, Ta, In, Mo, Mn, Co, Sn, Ni, Mg, Re, Be, Ga, and Ru, or an alloy thereof.

In some embodiments, the interconnect insulating layer 173 may include oxide or nitride. For example, the interconnect insulating layer 173 may include silicon oxide or silicon nitride. In some embodiments, the interconnect insulating layer 173 may include an insulating material including a photo imageable dielectric (PID) material, a photosensitive polyimide (PSPI) material, etc.

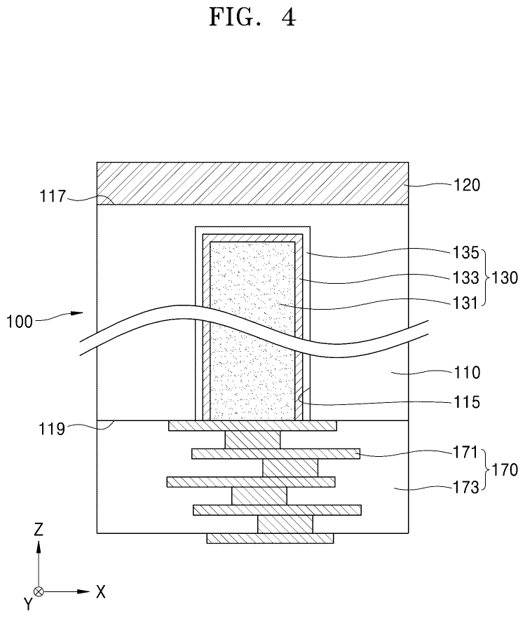

FIGS. 4 through 9 are cross-sectional views illustrating a manufacturing method of the first semiconductor chip 100, according to embodiments.

Referring to FIG. 4, the first semiconductor substrate 110 including the upper surface 117 and the lower surface 119 opposite to each other may be prepared. The first semiconductor substrate 110 may include, for example, a semiconductor wafer. Next, the through hole 115 partially penetrating the first semiconductor substrate 110 may be formed. The through hole 115 may extend from the lower surface 119 to the upper surface 117 of the first semiconductor substrate 110. After the through hole 115 is formed in the first semiconductor substrate 110, on the inner sidewall of the first semiconductor substrate 110 defining the through hole 115 of the first semiconductor substrate 110, a via insulating layer 135, a conductive barrier layer 133, and a conductive plug 131 may be sequentially formed. The conductive plug 131, the conductive barrier layer 133, and the via insulating layer 135 may form the through electrode 130. After the through electrode 130 is formed, the interconnect structure 170 may be formed under the lower surface 119 of the first semiconductor substrate 110. The interconnect structure 170 may be formed by using, for example, a damascene process.

The first insulating layer 120 may be deposited on the upper surface 117 of the first semiconductor substrate 110. The first insulating layer 120 may extend lengthwise along the upper surface 117 of the first semiconductor substrate 110 with a constant thickness. The first insulating layer 120 may be formed by using a deposition process, and the deposition process may include one of a PVD method, an atomic layer deposition (ALD) method, or a combination thereof.

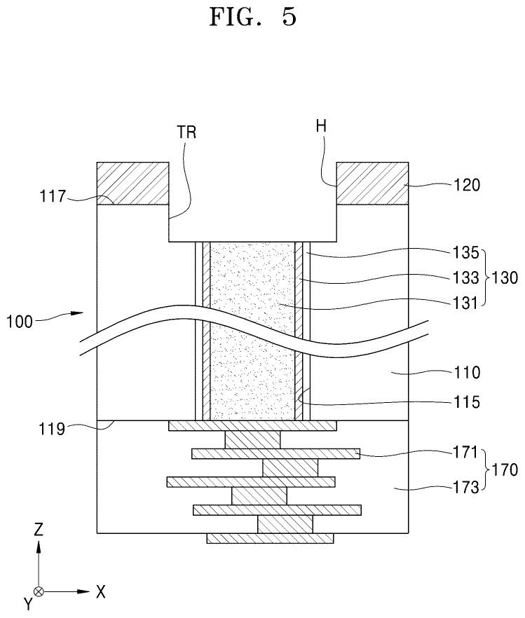

Referring to FIG. 5, the trench TR penetrating an entire portion of the first insulating layer 120 and a portion of the first semiconductor substrate 110 in the vertical direction (Z direction) may be formed. In FIG. 5, the trench TR is illustrated as having a constant diameter in the vertical direction (Z direction), but is not limited thereto.

The width of the trench TR in the horizontal direction (for example, X direction and/or Y direction) may be greater than the width of the first through electrode 130 in the horizontal direction (for example, X direction and/or Y direction). The trench TR may be formed to overlap the first through electrode 130 in the vertical direction (Z direction), and it may be desirable that the center of the trench TR coincides with the center of the first through electrode 130. In addition, in a process of forming the trench TR by etching the first insulating layer 120 and the first semiconductor substrate 110, portions of the first conductive barrier layer 133 and the first via insulating layer 135 of the first through electrode 130 may be etched. However, in the process of etching a portion of the first semiconductor substrate 110, the first conductive plug 131 may function as an etching stop layer. Accordingly, on the bottom surface of the trench TR, the upper surface of the first conductive plug 131 may be completely exposed.

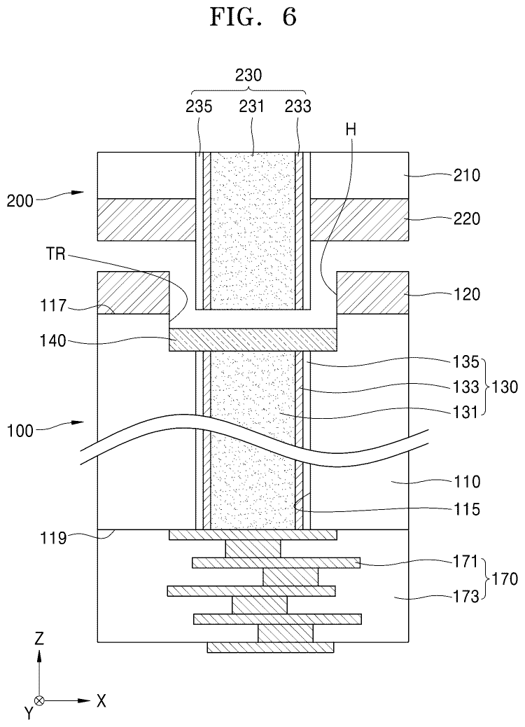

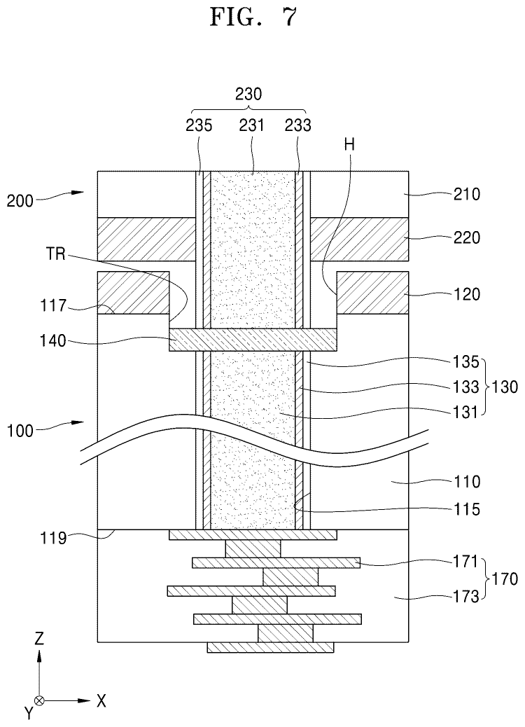

Referring to FIGS. 6 and 7, the second semiconductor chip 200 may be aligned with the first semiconductor chip 100. Thereafter, the second through electrode 230 may be attached on the upper surface of the bonding pad 140. The second through electrode 230 may be aligned such that the center line of the second through electrode 230 coincides with the center line of the first through electrode 130. To bond the second through electrode 230 to the bonding pad 140, a process atmosphere at a first temperature may be provided.

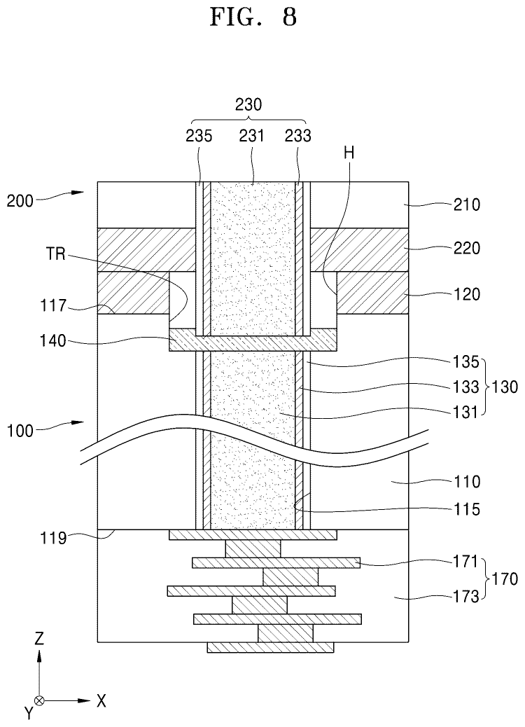

Referring to FIG. 8, the first insulating layer 120 may be attached to the second insulating layer 220. After the lower surface of the second insulating layer 220 contacts the upper surface of the first insulating layer 120, heat may be applied for bonding. The upper surface of the first insulating layer 120 and the lower surface of the second insulating layer 220 may each have proper bonding adhesion force by using a plasma treatment process and/or a wet treatment process. The process of bonding the first insulating layer 120 to the second insulating layer 220 may be performed by using a direct bonding method, for example, a hybrid direct bonding method. To bond the first insulating layer 120 to the second insulating layer 220, a process atmosphere at a second temperature higher than the first temperature may be provided.

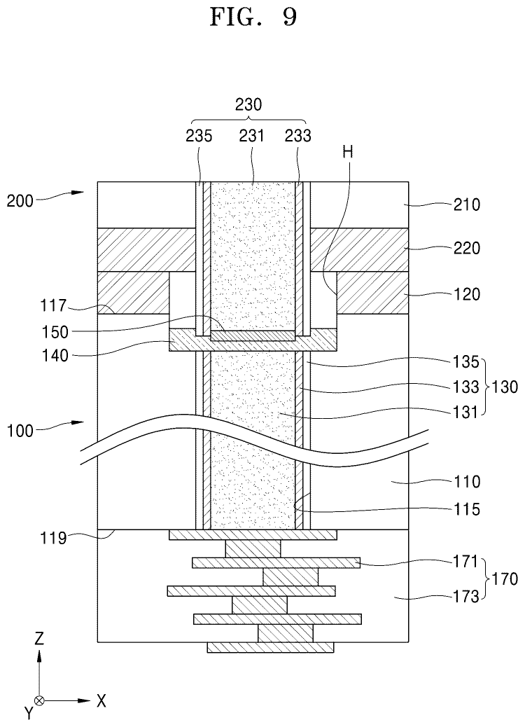

Referring to FIG. 9, the alloy pad 150 may be formed at a portion where the bonding pad 140 is bonded to the first conductive plug 131 of the first insulating layer 120. The alloy pad 150 may include intermetallic compound. The alloy pad 150 may include a compound formed by bonding of the first conductive plug 131 to the bonding pad 140. The alloy pad 150 may be formed by a metal material constituting the bonding pad 140 penetrating the first conductive plug 131. Alternatively, the alloy pad 150 may be formed by a metal material constituting the first conductive plug 131 penetrating the bonding pad 140. To form the alloy pad 150 between the second conductive plug 231 and the bonding pad 140, a process atmosphere at a third temperature higher than the second temperature may be provided.

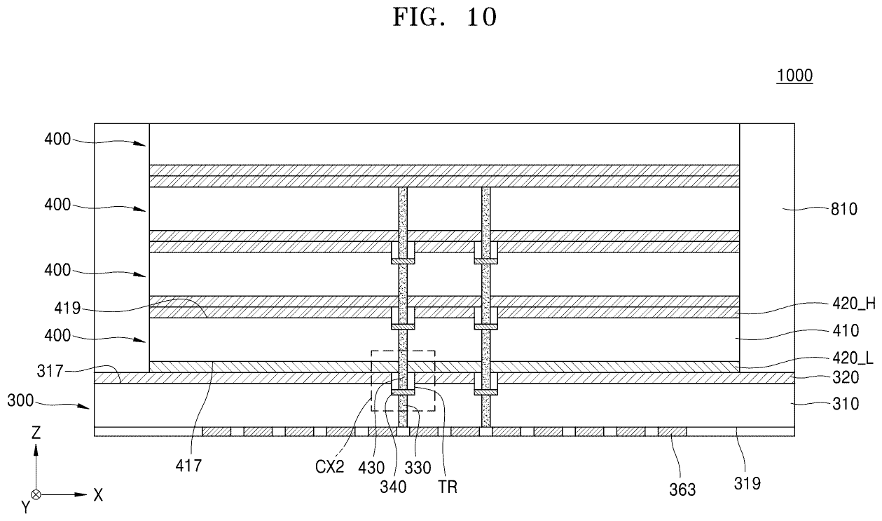

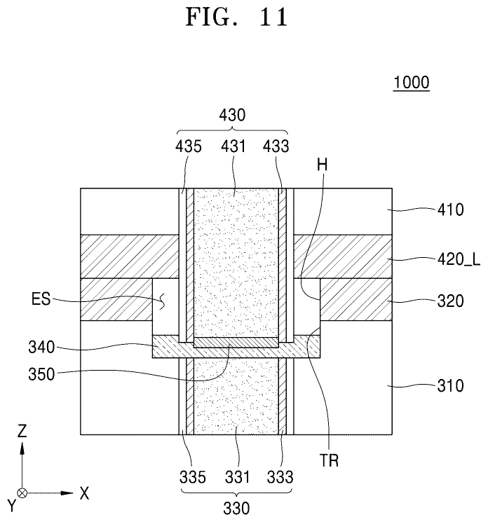

FIG. 10 is a cross-sectional view of a semiconductor package 1000 according to an embodiment, and FIG. 11 is an enlarged view of region “CX2” in FIG. 10.

Referring to FIGS. 10 and 11, the semiconductor package 1000 may include a first semiconductor chip 300 and a plurality of second semiconductor chips 400. The plurality of second semiconductor chips 400 may be mutually stacked on the first semiconductor chip 300 in the vertical direction (for example, Z direction). In FIG. 10, the semiconductor package 1000 is illustrated including four second semiconductor chips 400, but the number of second semiconductor chips 400 is not limited thereto. For example, the semiconductor package 1000 may include two or more second semiconductor chips 400. In some embodiments, the semiconductor package 1000 may include a multiple of four of second semiconductor chips 400. The semiconductor package 1000 may be referred to as a sub semiconductor package.

The first semiconductor chip 300 may be electrically connected to the lowermost second semiconductor chip 400 among the plurality of second semiconductor chips 400, exchange signals therewith, and provide power and ground thereto. Among the plurality of second semiconductor chips 400, two second semiconductor chips 400 adjacent to each other may be electrically connected to each other, exchange signals with each other, and provide or receive power and ground to and from each other.

The first semiconductor chip 300 may include a first semiconductor substrate 310 having an active surface 319 and an inactive surface 317 opposite to each other, a first interconnect structure (not illustrated) formed on the active surface 319 of the first semiconductor substrate 310, a plurality of first through electrodes 330 connected to an interconnect pattern of the first interconnect structure (not illustrated) and penetrating at least a portion of the first semiconductor chip 300, and a plurality of bonding pads 340 on the first semiconductor substrate 310 and connected to the plurality of first through electrodes 330. The first through electrode 330 may include a first conductive plug 331, a first conductive barrier layer 333, and a first via insulating layer 335.

The first semiconductor substrate 310 may be substantially the same as or similar to the semiconductor substrate 110 illustrated in FIG. 1, the first interconnect structure (not illustrated) may be substantially the same as or similar to the interconnect structure 170 illustrated in FIG. 1, the first through electrode 330 may be substantially the same as or similar to the through electrode 130 illustrated in FIG. 1, the bonding pad 340 may be substantially the same as or similar to the bonding pad 140 illustrated in FIG. 1, the alloy pad 350 may be substantially the same as or similar to the alloy pad 150, the first insulating layer 320 may be substantially the same as or similar to the pad insulating layer 120 illustrated in FIG. 1, and thus, detailed descriptions thereof are omitted. The first semiconductor chip 300 may further include a plurality of interconnect pads 363 connected to the first interconnect structure (not illustrated). In the semiconductor package 1000, the first semiconductor chip 300 may be arranged such that the active surface 319 of the first semiconductor substrate 310 faces a lower side of the first semiconductor substrate 310, and the inactive surface 317 of the first semiconductor substrate 310 faces an upper side of the first semiconductor substrate 310.

The second semiconductor chip 400 may include a second semiconductor substrate 410 having an inactive surface 417 and an active surface 419 opposite to each other, a plurality of second through electrodes 430 penetrating at least a portion of the second semiconductor chip 400, and a second lower end insulating layer 420_L arranged on the inactive surface 417 of the second semiconductor substrate 410. In addition, the second semiconductor chip 400 may include a second upper end insulating layer 420_H arranged on the active surface 419 of the second semiconductor chip 400. The second through electrode 430 may include a second conductive plug 431, a second conductive barrier layer 433, and a second via insulating layer 435.

The second semiconductor substrate 410 may be substantially the same as or similar to the second semiconductor substrate 210 illustrated in FIG. 1, the second through electrode 430 may be substantially the same as or similar to the second through electrode 230 illustrated in FIG. 1, the second lower end insulating layer 420_L may be substantially the same as or similar to the second insulating layer 220 illustrated in FIG. 1, and thus, detailed descriptions thereof are omitted.

In some embodiments, at least one of the first semiconductor chip 300 and the second semiconductor chip 400 may include a memory semiconductor chip. In some embodiments, at least one of the first semiconductor chip 300 and the second semiconductor chip 400 may include a logic chip. The logic chip may include processing circuitry such as a central processing unit (CPU) chip, a graphics processing unit (GPU) chip, or an application processor (AP) chip.

In some embodiment, the semiconductor package 1000 including the first semiconductor chip 300 and the plurality of second semiconductor chips 400 may be referred to as a high bandwidth memory (HBM) dynamic random access memory (RAM) (DRAM) (HBM DRAM) semiconductor chip. For example, the first semiconductor chip 300 may include a buffer chip including a serial-parallel conversion circuit and controlling the plurality of second semiconductor chips 400, and the plurality of second semiconductor chips 400 may include a core chip including DRAM memory cells. In some embodiments, the first semiconductor chip 300 may be referred to as a master chip, and each of the plurality of second semiconductor chips 400 may be referred to as a slave chip.

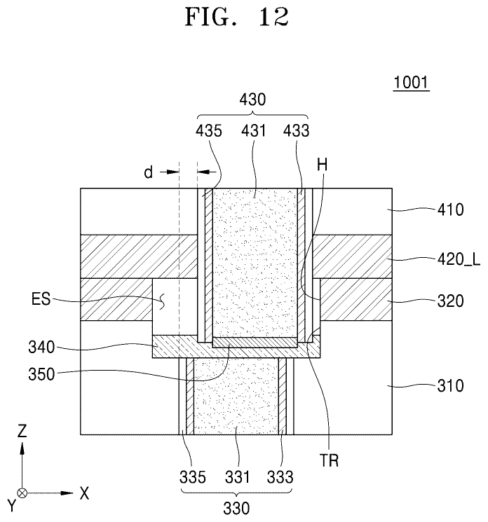

FIG. 12 is a cross-sectional view of a semiconductor package 1001 according to another embodiment. The semiconductor package 1001 illustrated in FIG. 12 may, when compared with the semiconductor package 1000 illustrated in FIG. 11, may be almost the same as or similar to the semiconductor package 1000 illustrated in FIG. 11, except that the first through electrode 330 is misaligned with the second through electrode 430. Accordingly, descriptions of the components given with reference to FIG. 11 are omitted or simplified.

Referring to FIG. 12, the second through electrode 430 may be misaligned with the first through electrode 330 by a first distance d in the vertical direction (Z direction). In other words, the sidewall of the first via insulating layer 335 of the first through electrode 330 and the sidewall of the second via insulating layer 435 of the second through electrode 430 may be apart from each other by the first distance d in the horizontal direction (for example, X direction and/or Y direction). However, the second through electrode 430 may be arranged in the trench TR of the first semiconductor substrate 310 and in the hole H of the first insulating layer 120. Even though the second through electrode 430 is misaligned with the first through electrode 330 by the first distance d, because the second through electrode 430 is bonded to the bonding pad 340, the first through electrode 330 and the second through electrode 430 may be electrically connected to each other.

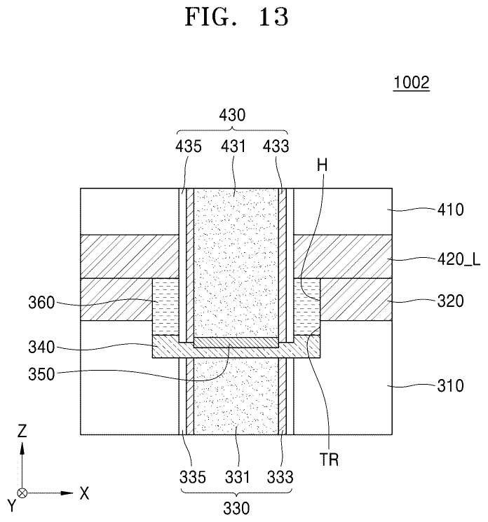

FIG. 13 is a cross-sectional view of a semiconductor package 1002 according to another embodiment. The semiconductor package 1002 illustrated in FIG. 13 may, when compared with the semiconductor package 1000 illustrated in FIG. 11, may be almost the same as or similar to the semiconductor package 1000 illustrated in FIG. 11, except that an insulating member 360 burying the trench TR of the first semiconductor substrate 310 and the hole H of the first insulating layer 320 is further included. Accordingly, descriptions of the components already given with reference to FIG. 11 are omitted or simplified.

Referring to FIG. 13, the semiconductor package 1002 according to the embodiment may further include the insulating member 360 burying the trench TR of the first semiconductor substrate 310 and the hole H of the first insulating layer 320. As the insulating member 360 burying the hole H is arranged, an empty space between the second via insulating layer 435 and a second insulating layer 320 may not occur. The insulating member 360 may include, for example, silicon oxide or silicon nitride.

The lower surface of the insulating member 360 may be in contact with the bonding pad 340, and the upper surface opposite to the lower surface of the insulating member 360 may be in contact with the second insulating layer 320. In addition, one side surface of the insulating member 360 may be in contact with the first semiconductor substrate 310 and the first insulating layer 320, and the other side surface opposite to the one side surface of the insulating member 360 may be in contact with the second via insulating layer 435.

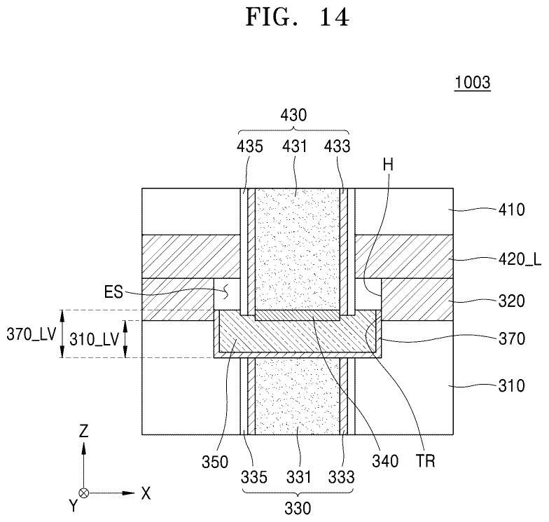

FIG. 14 is a cross-sectional view of a semiconductor package 1003 according to another embodiment. The semiconductor package 1003 illustrated in FIG. 14 may, when compared with the semiconductor package 1000 illustrated in FIG. 11, may be almost the same as or similar to the semiconductor package 1000 illustrated in FIG. 11, except that a pad barrier layer 370 is further included. Accordingly, descriptions of the components given with reference to FIG. 11 are omitted or simplified.

Referring to FIG. 14, the semiconductor package 1003 according to the embodiment may include the bonding pad 340 bonded to the second through electrode 430. In this case, the semiconductor package 1003 may further include the pad barrier layer 370 conformally covering the side surface and the lower surface of the bonding pad 340. However, the upper surface of the bonding pad 340 may not be covered by the pad barrier layer 370 and may be exposed at the opening portion ES in the hole H of the first insulating layer 320.

With a reference to the bottom of the trench TR, a vertical level 370_LV of the uppermost end of the pad barrier layer 370 may be higher than a vertical level 310_LV of the uppermost end of the first semiconductor substrate 310. Accordingly, an area, in which the bonding pad 340 overlaps the first insulating layer 320 in the vertical direction (Z direction), may occur. However, because the sidewall of the bonding pad 340 is covered by the pad barrier layer 370, a conductive material of the bonding pad 340 may be limited and/or prevented from infiltrating the first insulating layer 320.

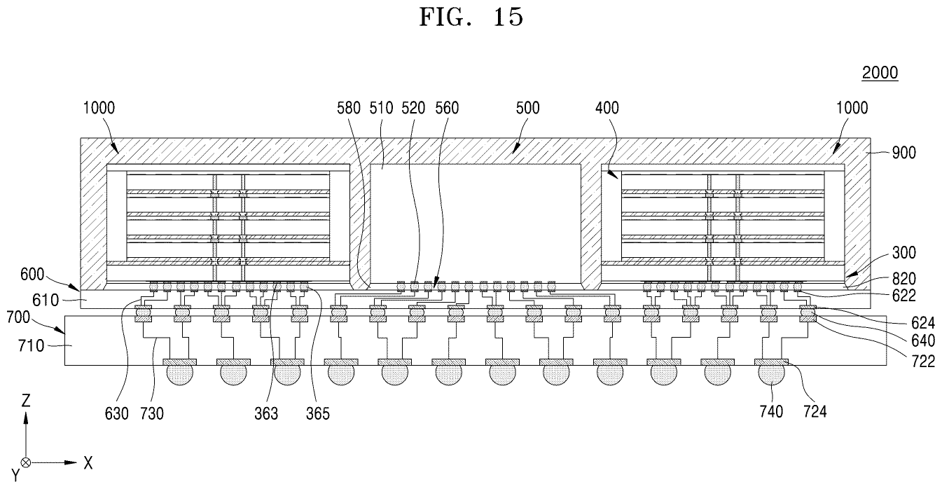

FIG. 15 is a cross-sectional view of a semiconductor package 2000 according to another embodiment.

Referring to FIG. 15, the semiconductor package 2000 may include a main board 700 including an interposer 600 mounted thereon, at least one sub semiconductor package 1000 attached to the interposer 600 and including the first semiconductor chip 300 and the plurality of second semiconductor chips 400, and a third semiconductor chip 500. In FIG. 15, the sub semiconductor package 1000 is illustrated as corresponding to the semiconductor package 1000 illustrated in FIG. 10. The sub semiconductor package 1000 is described with reference to FIG. 10 together. In addition, the semiconductor package 2000 may also be referred to as a system.

The sub semiconductor package 1000 may be attached to the interposer 600 by using a plurality of first connection bumps 365. The plurality of first connection bumps 365 may be respectively attached to a plurality of first connection pads 363 and may be electrically connected to a first interconnect structure (not illustrated) of the first semiconductor chip 300. The plurality of first connection bumps 365 may provide at least one of signals, power, or a ground to the sub semiconductor package 1000.

In FIG. 15, the semiconductor package 2000 is illustrated as including two sub semiconductor packages 1000, but is not limited thereto. For example, the semiconductor package 2000 may include one sub semiconductor package 1000, or three or more sub semiconductor packages 1000.

The third semiconductor chip 500 may include a third semiconductor substrate 510 including a semiconductor element formed on the active surface thereof, and a plurality of connection pads 520. In some embodiments, each of the plurality of connection pads 520 may include at least one of Al, Cu, and Ni. The third semiconductor chip 500 may be attached to the interposer 600 by using a plurality of second interconnect bumps 560. The plurality of second connection bumps 560 may be respectively attached to the plurality of connection pads 520. The third semiconductor chip 500 may include a logic chip. For example, the third semiconductor chip 500 may include a CPU chip, a GPU chip, or an AP chip.

Because the third semiconductor substrate 510 is substantially similar to the first semiconductor substrate 110 or the second semiconductor substrate 210 illustrated in FIG. 1, and the second connection bump 560 is similar to the first connection bump 365, detailed descriptions thereof are omitted.

The interposer 600 may include a base layer 610, a plurality of first upper surface pads 622 and a plurality of first lower surface pads 624 respectively arranged on the upper surface and the lower surface of the base layer 610, and a plurality of first interconnect paths 630 electrically connecting the first upper surface pad 622 to the first lower surface pad 624 via the base layer 610. The base layer 610 may include a semiconductor material, glass, ceramic, or plastic. For example, the base layer 610 may include silicon. The plurality of first interconnect paths 630 may include an interconnect layer connected to the plurality of first upper surface pads 622 and/or the plurality of first lower surface pads 624 on the upper surface and/or the lower surface of the base layer 610, and/or an internal through electrode provided inside the base layer 610 and electrically and respectively connecting the plurality of first upper surface pads 622 to the plurality of first lower surface pads 624. The plurality of first connection bumps 365 electrically connecting the sub semiconductor package 1000 to the interposer 600 or the plurality of second connection bumps 560 electrically connecting the third semiconductor chip 500 to the interposer 600 may be respectively connected to the plurality of first upper surface pads 622.

A first underfill layer 820 may be arranged between the sub semiconductor package 1000 and the interposer 600, and a second underfill layer 580 may be arranged between the third semiconductor chip 500 and the interposer 600. The first underfill layer 820 may surround the first connection bump 365, and the second underfill layer 580 may surround the second connection bump 560.

The semiconductor package 2000 may further include a package molding layer 900 surrounding side surfaces of the sub semiconductor package 1000 and the third semiconductor chip 500 on the interposer 600. The package molding layer 900 may include, for example, an epoxy mold compound (EMC). In some embodiments, the package molding layer 900 may cover the sub semiconductor package 1000 and the upper surface of the third semiconductor chip 500. In some embodiments, the package molding layer 900 may not cover the sub semiconductor package 1000 and the upper surface of the third semiconductor chip 500. For example, a heat dissipating member may be attached to the sub semiconductor package 1000 and the third semiconductor chip 500 with a thermal interface material (TIM) layer therebetween.

A plurality of board connection terminals 640 may attached to the plurality of first lower surface pads 624. The plurality of board connection terminals 640 may electrically connect the interposer 600 to the main board 700.

The main board 700 may include a base board layer 710, a plurality of second upper surface pads 722 and a plurality of second lower surface pads 724 respectively arranged on an upper surface and a lower surface of the base board layer 710, and a plurality of second interconnect paths 730 electrically and respectively connecting the plurality of second upper surface pads 722 to the plurality of second lower surface pads 724 via the base board layer 710.

In some embodiments, the main board 700 may include a printed circuit board. For example, the main board 700 may include a multi-layer printed circuit board. The base board layer 710 may include at least one material selected from phenol resin, epoxy resin, and polyimide.

A solder resist layer (not illustrated) exposing the plurality of second upper surface pads 722 and the plurality of second lower surface pads 724 may be formed on the upper surface and the lower surface of the base board layer 710, respectively. The plurality of board connection terminals 640 may be connected to the plurality of second upper surface pads 722, and a plurality of external connection terminals 740 may be connected to the plurality of second lower surface pads 724. The plurality of board connection terminals 640 may electrically connect between the plurality of first lower surface pads 624 and the plurality of second upper surface pads 722. The plurality of external connection terminals 740 connected to the plurality of second lower surface pads 724 may electrically and physically connect between the semiconductor package 2000 and an external device.

In some embodiments, the semiconductor package 2000 may not include the main board 700, and the plurality of board connection terminals 640 of the interposer 600 may function as an external connection terminal.

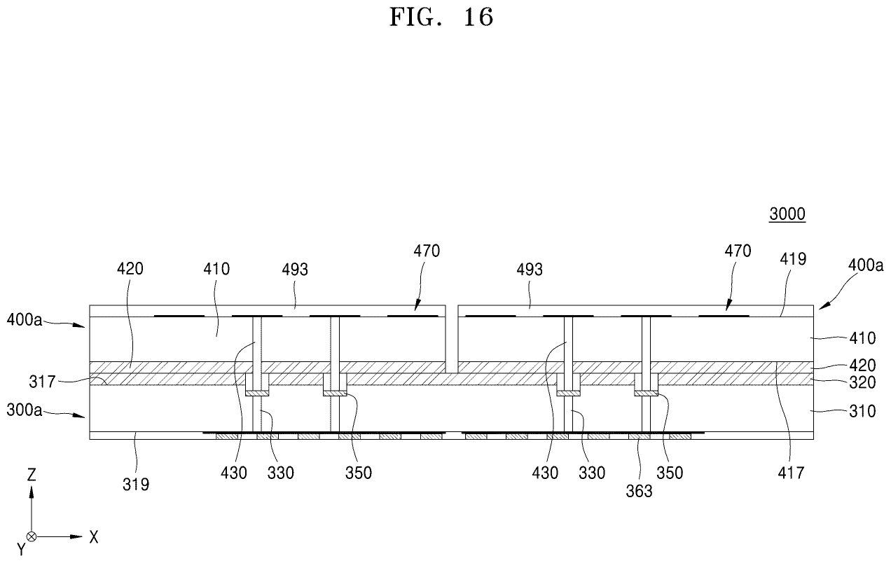

FIG. 16 is a cross-sectional view of a semiconductor package 3000 according to another embodiment. Hereinafter, duplicate descriptions already given are omitted.

Referring to FIG. 16, the semiconductor package 3000 may include a first semiconductor chip 300a and a plurality of second semiconductor chips 400a. The plurality of second semiconductor chips 400a may be stacked on the first semiconductor chip 300a and may be arranged side-by-side on the upper surface of the first semiconductor chip 300a. Although FIG. 16 illustrates that two second semiconductor chips 400a are stacked on the first semiconductor chip 300a, three or more second semiconductor chips 400a may also be stacked in parallel with each other on the first semiconductor chip 300a.

In some embodiments, the semiconductor package 3000 may also include one or more second semiconductor chips 400a stacked over two or more first semiconductor chips 300a apart from each other in the horizontal direction. In some embodiments, the plurality of second semiconductor chips 400a may include all homogeneous semiconductor chips. In some embodiments, the plurality of second semiconductor chips 400a may include heterogeneous semiconductor chips. Each of the plurality of second semiconductor chips 400a and the first semiconductor chip 300a may be bonded to each other by using a direct bonding method. The second semiconductor chip 400a may include a second semiconductor substrate 410 having an inactive surface 417 and an active surface 419 opposite to each other, a second interconnect structure 470 formed on the active surface 419 of the second semiconductor substrate 410, a plurality of second through electrodes 430 connected to the second interconnect structure 470 and penetrating at least a portion of the second semiconductor chip 400, and a second lower end insulating layer 420 arranged on the inactive surface 417 of the second semiconductor substrate 410. The bonding between each of the plurality of second semiconductor chips 400a and the first semiconductor chip 300a may be similar to the bonding between the first semiconductor chip 300 and the second semiconductor chip 400 in FIG. 1, and thus, detailed descriptions thereof are omitted.

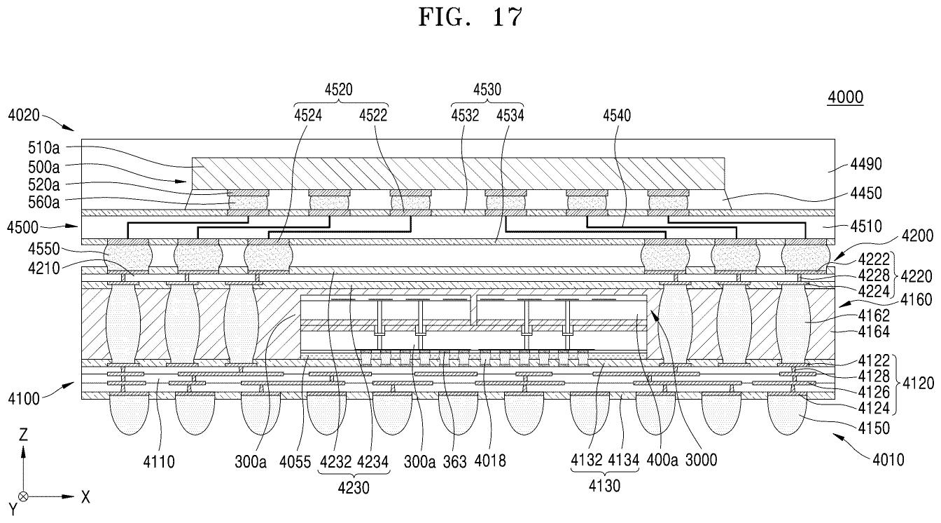

FIG. 17 is a cross-sectional view of a semiconductor package 4000 according to another embodiment.

Referring to FIG. 17, the semiconductor package 4000 may include an upper semiconductor package 4020 stacked on a lower semiconductor package 4010. The semiconductor package 4000 may include a package on package.

The lower semiconductor package 4010 may include a support interconnect structure 4100, an expansion layer 4160 arranged on the support interconnect structure 4100, the semiconductor package 3000 arranged in the expansion layer 4160, and a cover interconnect structure 4200 arranged on the expansion layer 4160. The semiconductor package 3000 may be the semiconductor package 3000 illustrated in FIG. 16.

The lower semiconductor package 4010 may include a fan-out semiconductor package in which the horizontal width and plan area of the support interconnect structure 4100, and the horizontal width and plan area of the cover interconnect structure 4200 have values greater than the horizontal width and plan area of the semiconductor package 3000, respectively. In some embodiments, the horizontal width and the plan area of the support interconnect structure 4100 may be the same as the horizontal width and the plan area of the cover interconnect structure 4200, respectively. In some embodiments, corresponding side surfaces of the support interconnect structure 4100, the expansion layer 4160, and the cover interconnect structure 4200 may be coplanar with each other.

The support interconnect structure 4100 may be referred to as a lower interconnect structure, and the cover interconnect structure 4200 may be referred to as an upper interconnect structure.

The support interconnect structure 4100 and the cover interconnect structure 4200 may include, for example, a printed circuit board, a ceramic board, a package manufacturing wafer, or an interposer. In some embodiments, the support interconnect structure 4100 and the cover interconnect structure 4200 may include multi-layer printed circuit boards. When the support interconnect structure 4100 includes a PCB, the support interconnect structure 4100 may be referred to as a support printed circuit board, a lower printed circuit board, or a first printed circuit board. When the cover interconnect structure 4200 is a printed circuit board, the cover interconnect structure 4200 may be referred to as a cover printed circuit board, an upper printed circuit board, or a second printed circuit board.

The support interconnect structure 4100 may include at least one first base insulating layer 4110 and a plurality of first interconnect patterns 4120. The cover interconnect structure 4200 may include at least one second base insulating layer 4210 and a plurality of second interconnect patterns 4220. The first base insulating layer 4110 and the second base insulating layer 4210 may include at least one material of phenol resin, epoxy resin, and polyimide.

The plurality of first interconnect patterns 4120 may include a first upper surface interconnect pattern that is arranged on an upper surface of at least one first base insulating layer 4110 and includes a plurality of first upper surface pads 4122; a first lower surface interconnect pattern that is arranged on a lower surface of at least one first base insulating layer 4110 and includes a plurality of first lower surface pads 4124; and a plurality of first conductive vias 4128 which penetrate at least one first base insulating layer 4110 and electrically connect the plurality of first interconnect patterns 4120 to each other arranged on different interconnect layers from each other. In some embodiments, when the support interconnect structure 4100 includes a plurality of first base insulating layers 4110, the first interconnect pattern 4120 may further include a first internal interconnect pattern 4126 that forms an interconnect layer and is arranged between two first base insulating layers 4110 adjacent to each other.

The plurality of second interconnect patterns 4220 may include a second upper surface interconnect pattern that is arranged on an upper surface of the at least one second base insulating layer 4210 and includes a plurality of second upper surface pads 4222; a second lower surface interconnect pattern that is arranged on the lower surface of the at least one second base insulating layer 4210 and includes a plurality of second lower surface pads 4224; and a plurality of second conductive vias 4228 which penetrate the at least one second base insulating layer 4210 and electrically connect the second interconnect patterns 4220 to each other on different interconnect layers from each other. The first interconnect pattern 4120 and the second interconnect pattern 4220 may include Cu, Ni, stainless steel, or beryllium copper.

The support interconnect structure 4100 may further include a first solder resist layer 4130 arranged on an upper surface and a lower surface thereof. The first solder resist layer 4130 may include a first upper surface solder resist layer 4132 which covers an upper surface of at least one first base insulating layer 4110 and exposes the first upper surface pad 4122, and a first lower surface solder resist layer 4134 which covers a lower surface of the at least one first base insulating layer 4110 and exposes the first lower surface pad 4124. In some embodiments, the first lower surface solder resist layer 4134 may be formed, but the first upper surface solder resist layer 4132 may not be formed.

The cover interconnect structure 4200 may further include a second solder resist layer 4230 on the upper surface and the lower surface thereof. The second solder resist layer 4230 may include a second upper surface solder resist layer 4232 which covers the upper surface of the at least one second base insulating layer 4210 and includes an opening for exposing the second upper pad 4222, and a second lower surface solder resist layer 4234 which covers the lower surface of the at least one second base insulating layer 4210 and includes an opening for exposing the second lower surface pad 4224.

A plurality of first chip connection terminals 4018 may be arranged between the plurality of first upper surface pads 4122 and the plurality of first connection pads 363 and may electrically connect the semiconductor package 3000 to the support interconnect structure 4100. For example, the plurality of first chip connection terminals 4018 may include solder balls or bumps. In some embodiments, an underfill layer 4055 surrounding the plurality of first chip connection terminals 4018 may be arranged between the semiconductor package 3000 and the support interconnect structure 4100. In some embodiments, the underfill layer 4055 may include a non-conductive film (NCF).

The semiconductor package 4000 may include a plurality of external connection terminals 4150 attached to the plurality of first lower surface pads 4124. For example, the height of each of the plurality of external connection terminals 4150 may be about 150 μm. For example, the plurality of external connection terminals 4150 may include solder balls.

The expansion layer 4160 may include a plurality of connection structures 4162 and a filling member 4164 surrounding the plurality of connection structures 4162 and the semiconductor package 3000. The filling member 4164 may fill a space between the support interconnect structure 4100 and the cover interconnect structure 4200, and surround the semiconductor package 3000. The plurality of connection structures 4162 may be apart from the semiconductor package 3000 and arranged around the semiconductor package 3000. The plurality of connection structures 4162 may penetrate the filling member 4164 and electrically connect between the support interconnect structure 4100 and the cover interconnect structure 4200. The upper end and the lower end of each of the plurality of connection structures 4162 may contact and be connected to any one of the plurality of second lower surface pads 4224 of the cover interconnect structure 4200 and any one of the plurality of first upper surface pads 4122 of the support interconnect structure 4100.

The upper semiconductor package 4020 may include at least one third semiconductor chip 500a. The upper semiconductor package 4020 may be electrically connected to the lower semiconductor package 4010 via a plurality of package connection terminals 4550 attached to the plurality of second upper surface pads 4222 of the lower semiconductor package 4010.

The third semiconductor chip 500a may include a third semiconductor substrate 510a including a semiconductor element formed on an active surface thereof, and a plurality of chip connection pads 520a arranged on the active surface of the third semiconductor substrate 510a. At least one third semiconductor chip 500a may include a memory semiconductor chip.

In FIG. 17, at least one third semiconductor chip 500a included by the upper semiconductor package 4020 is illustrated as being mounted on a package base substrate 4500 in a flip chip method, but the embodiment is an example and is not limited thereto. The semiconductor package 4000 may include, as an upper semiconductor package, a semiconductor package of all types that includes at least one third semiconductor chip 500a and the package connection terminal 4550 is attachable to a lower side of the semiconductor package 4000 to be electrically connected to the lower semiconductor package 4010.

The package base substrate 4500 may include a base board layer 4510 and a plurality of board pads 4520 arranged on an upper surface and a lower surface of the base board layer 4510. The plurality of board pads 4520 may include a plurality of board upper surface pads 4522 arranged on the upper surface of the base board layer 4510 and a plurality of board lower surface pads 4524 arranged on the lower surface of the base board layer 4510. In some embodiments, the package base substrate 4500 may include a printed circuit board. On the upper surface and the lower surface of the base board layer 4510, a board solder resist layer 4530 exposing the plurality of board pads 4520 may be formed. The board solder resist layer 4530 may include an upper surface board solder resist layer 4532 which covers the upper surface of the base board layer 4510 and exposes the plurality of board upper surface pads 4522, and a lower surface board solder resist layer 4534 which covers the lower surface of the base board layer 4510 and exposes the plurality of board lower surface pads 4524.

The package base substrate 4500 may include a board interconnect 4540 electrically connecting between the plurality of board upper surface pads 4522 and the plurality of board lower surface pads 4524 inside the base board layer 4510. The board interconnect 4540 may include a board interconnect line and a board interconnect via.

The plurality of board upper surface pads 4522 may be electrically connected to the third semiconductor chip 500a. For example, a plurality of second chip connection terminals 560a may be arranged between the plurality of chip connection pads 520a of the third semiconductor chip 500a and the plurality of board upper surface pads 4522 of the package base substrate 4500, and may electrically connect the third semiconductor chip 500a to the package base substrate 4500. In some embodiments, a second underfill layer 4450 surrounding the plurality of second chip connection terminals 560a may be arranged between the third semiconductor chip 500a and the package base substrate 4500. The second underfill layer 4450 may include, for example, epoxy resin formed by using a capillary underfill method.

A molding layer 4490 surrounding the third semiconductor chip 500a may be arranged on the package base substrate 4500. The molding layer 4490 may include, for example, an EMC.

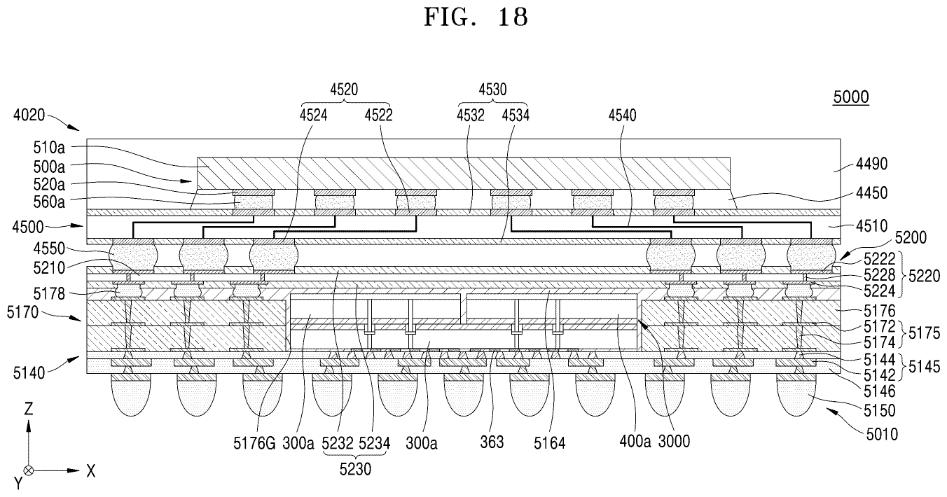

FIG. 18 is a cross-sectional view of a semiconductor package 5000 according to another embodiment.

Referring to FIG. 18, the semiconductor package 5000 may include the upper semiconductor package 4020 stacked on a lower semiconductor package 5010. The upper semiconductor package 4020 may be substantially the same as the upper semiconductor package 4020 described with reference to FIG. 17, and thus, detailed descriptions thereof are omitted.

The lower semiconductor package 5010 may include a support interconnect structure 5140, an expansion layer 5170 which is arranged on the support interconnect structure 5140 and includes a mounting space 5176G, the semiconductor package 3000 arranged inside the mounting space 5176G of the expansion layer 5170, and a cover interconnect structure 5200 arranged on the expansion layer 5170. The expansion layer 5170 may surround the periphery of the semiconductor package 3000. The semiconductor package 3000 may correspond to the semiconductor package 3000 illustrated in FIG. 16.

The lower semiconductor package 5010 may include a fan-out semiconductor package. In some embodiments, the expansion layer 5170 may include a panel board, and the lower semiconductor package 5010 may include a fan-out panel level package (FOPLP). For example, the lower semiconductor package 5010 may include a chip first FOPLP in which the support interconnect structure 5140 is formed after the cover interconnect structure 5200 is attached on the expansion layer 5170. The support interconnect structure 5140 may be referred to as a reinterconnect layer.

In some embodiments, a horizontal width and a plan area of the mounting space 5176G may be greater than a horizontal width and a plan area of a footprint constituted by the semiconductor package 3000, respectively. A side surface of the semiconductor package 3000 may be apart from an internal surface of the mounting space 5176G.

The support interconnect structure 5140 may include a reinterconnect conductive structure 5145 and a plurality of reinterconnect insulating layers 5146. The reinterconnect conductive structure 5145 and a reinterconnect insulating layer 5146 may be referred to as an interconnect pattern and a base insulating layer, respectively. The reinterconnect conductive structure 5145 may include a plurality of reinterconnect line patterns 5142 arranged on at least one of the upper surface and the lower surface of each of the plurality of reinterconnect insulating layers 5146, and a plurality of reinterconnect vias 5144 which penetrate at least one reinterconnect insulating layer 5146 of the plurality of reinterconnect insulating layers 5146 and are in contact with and connected to some of the plurality of reinterconnect line patterns 5142. In some embodiments, at least some of the plurality of reinterconnect line patterns 5142 may be formed in one body together with some of the plurality of reinterconnect vias 5144. In some embodiments, the plurality of reinterconnect vias 5144 may have a tapered shape, in which a horizontal width decreases and extends from a lower side to an upper side of the plurality of reinterconnect vias 5144. In other words, the plurality of reinterconnect vias 5144 may have a decreasing horizontal width toward a first semiconductor chip 200a. A plurality of first connection pads 263 of the semiconductor package 3000 may be electrically connected to the reinterconnect conductive structure 5145.

The expansion layer 5170 may include, for example, a printed circuit board, a ceramic substrate, a package manufacturing wafer, or an interposer. In some embodiments, the expansion layer 5170 may include a multi-layer printed circuit board. The mounting space 5176G may be formed as an opening or a cavity in the expansion layer 5170. The mounting space 5176G may be formed in some area, for example, the center area of the expansion layer 5170. The mounting space 5176G may be recessed from an upper surface of the expansion layer 5170 to a certain depth, or may be formed to extend from the upper surface to a lower surface of the expansion layer 5170 and be open. The expansion layer 5170 may include a plurality of connection structures 5175 and at least one substrate base 5176. The connection structure 5175 may include a connection interconnect pattern 5172 and a connection conductive via 5174.

The lower semiconductor package 5010 may further include a filling member 5164 filling a space between the semiconductor package 3000 and the expansion layer 5170, and a space between the expansion layer 5170 and the cover interconnect structure 5200. The filling member 5164 may surround the semiconductor package 3000. The filling member 5164 may include, for example, an EMC.

On the expansion layer 5170, the cover interconnect structure 5200 including a second interconnect pattern 5220 electrically connected to the connection structure 5175 may be arranged. The cover interconnect structure 5200 may include at least one second base insulating layer 5210 and the plurality of second interconnect patterns 5220. The plurality of second interconnect patterns 5220 may include a second upper surface interconnect pattern that is arranged on the upper surface of the at least one second base insulating layer 5210 and includes a plurality of second upper surface pads 5222; a second lower surface interconnect pattern that is arranged on the lower surface of the at least one second base insulating layer 5210 and includes a plurality of second lower surface pads 5224; and a plurality of second conductive vias 5228 that penetrate the at least one second base insulating layer 5210 and electrically connect the second interconnect patterns 5220 to each other which are arranged on different interconnect layers from each other. In some embodiments, a plurality of internal connection terminals 5178 may be arranged between the connection structure 5175 and the plurality of second lower surface pads 5224, and may electrically connect the connection structure 5175 to the second interconnect pattern 5220.

While inventive concepts has been particularly shown and described with reference to embodiments thereof, it will be understood that various change in form and details may be made therein without departing from the spirit and scope of the following claims.

What is claimed is:

1. A semiconductor package comprising:
a semiconductor substrate defining a trench extending in a vertical direction from an upper surface of the semiconductor substrate, the vertical direction being perpendicular to the upper surface of the semiconductor substrate;
an insulating layer on the semiconductor substrate;
a first through electrode penetrating the semiconductor substrate;
a bonding pad in the trench, a first surface of the bonding pad being in contact with the first through electrode and a second surface of the bonding pad being opposite the first surface of the bonding pad; and
a second through electrode in contact with the second surface of the bonding pad,
wherein the second through electrode is apart from the insulating layer in a horizontal direction.

2. The semiconductor package of claim 1, wherein
with reference to the first surface of the bonding pad, a vertical level of an uppermost end of the second surface of the bonding pad is lower than a vertical level of an uppermost end of the semiconductor substrate.

3. The semiconductor package of claim 1, wherein the second surface of the bonding pad has a stepped profile.

4. The semiconductor package of claim 1, wherein the second through electrode comprises:
a conductive plug extending lengthwise in the vertical direction;
a conductive barrier layer on a side surface of the conductive plug; and
a via insulating layer on a side surface of the conductive barrier layer.

5. The semiconductor package of claim 4, further comprising:
an alloy pad between the conductive plug and the bonding pad, wherein
a lower surface of the alloy pad is offset with a lower surface of the conductive barrier layer and a lower surface of the via insulating layer.

6. The semiconductor package of claim 1, wherein an upper surface of the first through electrode is a coplanar surface with a bottom surface of the trench.

7. The semiconductor package of claim 1, wherein a side surface of the semiconductor substrate is coplanar with a side surface of the insulating layer in the trench.

8. The semiconductor package of claim 1, wherein
a side surface of the second through electrode is spaced apart from a side surface of the insulating layer and a side surface of the semiconductor substrate, such that an opening portion is defined,
the opening portion is between the side surface of the second through electrode and the side surface of the insulating layer, and
the opening portion is between the side surface of the second through electrode and the semiconductor substrate.

9. The semiconductor package of claim 1, wherein
in a plan view, a periphery portion of the bonding pad has a ring shape and extends continuously along a sidewall of the second through electrode.

10. The semiconductor package of claim 1, wherein the bonding pad comprises tin or germanium.

11. A semiconductor package comprising:
a first semiconductor substrate defining a trench extending in a vertical direction from an upper surface of the first semiconductor substrate, the vertical direction being perpendicular to the upper surface of the first semiconductor substrate;
a first insulating layer on the first semiconductor substrate, the first insulating layer including a hole corresponding to the trench;
a first through electrode penetrating the first semiconductor substrate;
a first bonding pad in the trench, a first surface of the first bonding pad facing the first through electrode, and a second surface of the first bonding pad being opposite the first surface of the first bonding pad and having a step;
a second semiconductor substrate on the first insulating layer;
a second insulating layer between the second semiconductor substrate and the first insulating layer, the second insulating layer being bonded to the first insulating layer; and
a second through electrode penetrating the second semiconductor substrate and the second insulating layer, the second through electrode being bonded to the second surface of the first bonding pad, wherein
the second through electrode is apart from the first insulating layer in a horizontal direction.

12. The semiconductor package of claim 11, wherein
a side surface of the second through electrode is spaced apart from a side surface of the first insulating layer and a side surface of the first semiconductor substrate, such that an opening portion is defined,
the opening portion is between the side surface of the second through electrode and the side surface of the first insulating layer, and
the opening portion is between the side surface of the second through electrode and the semiconductor substrate.

13. The semiconductor package of claim 11, further comprising:
an insulating member between a side surface of the second through electrode and a side surface of the first insulating layer, wherein
the insulating member is between the side surface of the second through electrode and the first semiconductor substrate.

14. The semiconductor package of claim 11, wherein the first insulating layer and the second insulating layer comprise silicon oxide.

15. The semiconductor package of claim 11, wherein the first through electrode and the second through electrode are offset with each other in the horizontal direction.

16. The semiconductor package of claim 11, wherein
in a cross-sectional view, a thickness of the first bonding pad decreases toward a center portion thereof.

17. The semiconductor package of claim 11, further comprising:
a pad barrier layer surrounding the first bonding pad and covering the first surface of the first bonding pad, wherein
the pad barrier layer is in contact with a portion of the first insulating layer and a portion of the first semiconductor substrate.

18. The semiconductor package of claim 17, wherein,
with reference to an upper surface of the first through electrode, a vertical level of an uppermost surface of the pad barrier layer is higher than a vertical level of an uppermost surface of the semiconductor substrate.

19. A semiconductor package comprising:
a first semiconductor chip and a second semiconductor chip bonded to each other,
wherein the first semiconductor chip includes
a first semiconductor substrate defining a trench extending in a vertical direction from an upper surface of the first semiconductor substrate,
a first insulating layer on the first semiconductor substrate,
a first through electrode penetrating the first semiconductor substrate, and
a bonding pad in the trench,
wherein the vertical direction is perpendicular to the upper surface of the first semiconductor substrate, a first surface of the bonding pad is in contact with the first through electrode, and a second surface of the bonding pad is opposite the first surface of the bonding pad, and
wherein the second semiconductor chip includes
a second semiconductor substrate,
a second insulating layer between the second semiconductor substrate and the first insulating layer, and
a second through electrode penetrating the second semiconductor substrate and the second insulating layer,
wherein the second through electrode is in contact with the second surface of the bonding pad, and
wherein the second through electrode is apart from the first insulating layer in a horizontal direction.

20. The semiconductor package of claim 19, wherein
the first through electrode includes
a first conductive plug extending lengthwise in the first semiconductor substrate in the vertical direction,
a first conductive barrier layer on a side surface of the first conductive plug, and
a first via insulating layer on a side surface of the first conductive barrier layer, and
the second through electrode includes
a second conductive plug extending lengthwise in the second semiconductor substrate in the vertical direction,
a second conductive barrier layer on a side surface of the second conductive plug, and
a second via insulating layer on a side surface of the second conductive barrier layer.
